(19) United States
(12) Patent Application Publication
(10) Pub. No.: US 2018/0265968 A1
(43) Pub. Date: Sep. 20, 2018

(54) COATING CHAMBER FOR IMPLEMENTING OF A VACUUM-ASSISTED COATING PROCESS, HEAT SHIELD, AND COATING PROCESS

(71) Applicant: OERLIKON SURFACE SOLUTIONS AG, PFAEFFIKON, Pfaeffikon (CH)

(72) Inventors: Joerg VETTER, Bergisch Gladbach (DE); Siegfried KRASSNITZER, Feldkirch (AT); Markus ESSELBACH, Feldkirch (AT)

(73) Assignee: OERLIKON SURFACE SOLUTIONS AG, PFAEFFIKON, Pfaeffikon (CH)

(21) Appl. No.: 15/544,428

(22) PCT Filed: Jan. 15, 2016
(86) PCT No.: PCT/EP2016/050840

§ 371 Date: Jul. 18, 2017

Related U.S. Application Data
(60) Provisional application No. 62/117,571, filed on Feb. 18, 2015.
(60) Provisional application No. 62/104,918, filed on Jan. 19, 2015.

(51) Int. Cl. C23C 16/44; C23C 16/46; C23C 14/54

(52) U.S. Cl. CPC C23C 16/4411; C23C 14/325; C23C 14/541; C23C 16/466

(57) ABSTRACT

The invention relates to a coating chamber (1) for performing a vacuum-assisted coating process, in particular PVD or CVD or electric arc coating chamber or hybrid coating chamber.

The coating chamber (1) comprises a heat shield (3, 31, 32, 33), which is arranged on a temperature-controllable chamber wall (2) of the coating chamber (1) and is intended for adjusting an exchange of a predeterminable amount of thermal radiation between the heat shield (3, 31, 32, 33) and the temperature-controllable chamber wall (2). According to the invention the heat shield (3, 31, 32, 33) comprises at least one exchangeable radiating shield (31), which is directly adjacent to an inner side (21) of the chamber wall (2), wherein a first radiation surface (311) of the radiating shield (31),that is directed towards the chamber wall (2) has a first predeterminable heat exchange coefficient (ε_{D1}) and a second radiation surface (312) of the radiating shield (31) that is directed away from the chamber wall (2) has a second predeterminable heat exchange coefficient (ε_{D2}), wherein the first heat exchange coefficient (ε_{D1}) higher than the second heat exchange coefficient (ε_{D2}). The invention further relates to a heat shield for a coating chamber as well as a coating method.

### CROSS-REFERENCE TO RELATED APPLICATIONS

The present application is a U.S. National Stage of International Patent Application No. PCT/EP2016/050840 filed Jan. 15, 2016, and claims the benefit of U.S. Provisional Application No. 62/117,571 filed Feb. 18, 2015 and of U.S. Provisional Application No. 62/104,918 filed Jan. 19, 2015. The disclosure of International Patent Application No. PCT/EP2016/050840 is expressly incorporated by reference herein in its entirety.

### BACKGROUND OF THE INVENTION

### 1. Field of the Invention

The invention relates to a coating chamber for performing a vacuum-assisted coating process, a heat shield for a coating chamber as well as a coating process.

### 2. Discussion of Background Information

Vacuum-assisted coating systems for coating or finishing of surfaces of different parts of all kind such as tools, respectively, housings for technical and non-technical devices or of other parts with functional coatings, in particular by plasma-assisted PVD and CVD processes, often for applying hard coatings comprising nitrides, carbides, borides, oxides and their mixtures, DLC or for applying other coatings must be configured such, that they can realize a high productivity at low costs having as much flexibility as possible of the realizable processes regarding adjusting the temperature of parts in industrial coating. The boundary conditions are among other things vacuum technical requirements regarding the required pumping times for realizing a sufficiently low starting pressure in the coating chamber of the coating system, fast and reliable cleaning of the interior of the coating chamber of parasitic inevitable coatings, but also the assurance of sufficiently high coating rates at a given maximum temperature of parts, which may not be exceeded in any case, as well as the setting of a minimum temperature, which should not fall below that, must be always reliably ensured during the coating process.

The coating chambers are often performed double-walled in the state of the art for a optimized cooling but also single-walled with cooling elements in critical selected areas, for example in shape of flanges for coating sources. The method, known to the person skilled in the art, for realizing short pumping times are smooth chamber walls for minimizing the desorption rate of the inevitable gas load in contact with ambient air with open chamber. An easy cleaning is realized by exchangeable foils normally applied to the chamber wall, and/or with interchangeable metal sheets fitted at the chamber wall.

However, in these arrangements known from the state of the art it is adverse, that the design of the coating chamber regarding to the flexible application for various temperature ranges at sufficiently high coating rates, in particular while maintaining a minimum or a maximum temperature of parts, respectively, is very limited by design. Furthermore the mentioned exchangeable foils have to be regularly changed or replaced, respectively, which causes additional costs.

The coating processes usually comprise also process steps, which can cause a heat input into the parts, either intended or also unintended due to the process conditions, which can lead to an increase of the substrate temperature, for example.

Prominent examples for such process steps include:

While pumping and heating the substrates, an intended heat input is generated by heating, for example by a radiant heater or an electron heater, until reaching a minimum starting temperature or a sufficiently low residual gas pressure.

While ion cleaning the surfaces of the parts, an intrinsically unintended heat input can occur, so to say as a side effect of the plasma processes, for example by accelerated ions for ion cleaning at the substrates and plasma sources, e.g. also by heat radiation or electron processes.

Also in the actual coating of the substrate surfaces an unintended heat input usually occurs as a side effect of the plasma processes (coating material) at the substrates and plasma sources (e.g. by heat radiation, electron processes).

Heat is thus intended or unintended introduced into the substrates in all three process steps mentioned. In practice, the substrates are usually arranged on rotating substrate holders inside the coating chamber, wherein the substrate holders can perform e.g. a single, a double or a triple rotation during operation for realizing sufficiently homogeneous coating results. Due to low process pressures a heat output is essentially possible only by heat radiation among the substrates and the colder surfaces, which are usually represented exclusively by the chamber wall during a process step.

For practical reasons, the person skilled in the art usually distinguishes two temperature ranges in the established coating processes, which are mentioned below as a reminder and specified for clarification.

### 1. Low Temperature Coating (NTB): Tsu≤250° C.

The industrial range of low temperature coating, abbreviated NTB, is at a maximum temperature of parts Tmax in the range of 150° C. to 250° C. However significant lower temperatures are required for galvanized plastics as substrate material. Since this is an exceptional case, it is not discussed in detail here and is referred to the corresponding literature.

The substrate starting temperatures, abbreviated Tsu, may not or only for a short time exceed the maximum permitted temperature of parts Tmax, which is defined by the materials of parts to be coated or by coating characteristics to be maintained, to ensure a reliable coating or to avoid a damage of the substrates, respectively. The processes are performed in such a way just for reasons of productivity (heating, ion cleaning, coating), that the process time is as short as possible, i.e. it is near the permitted thermal load of the substrates or the permitted coating temperature, respectively.

Various processes or material characteristics or specifications for the quality of the coating may be determinative for Tmax, respectively. Usually sufficiently long exceeding the maximum temperature Tmax leads for example to a negative influence to the substrate material, e.g. retained austenite transformation with ball bearing steels, whereby dimensional changes can occur, or even hardening (carburized steels).

However the coating characteristics to be realized e.g. may be determinative for the limit Tmax. So it is known, that the characteristics of certain coatings, for example DLC-coatings, in particular hard hydrogen free carbon coatings of type ta-C change negatively when exceeding a maximum temperature. More sp² C-C-bound states can be realized compared to sp³ C-C-bound states, for example.

### 2. High Temperature Coating (HTB): Tmin≤400° C.

The industrial range of high temperature coating, abbreviated HTB, is usually at a minimum temperature of parts Tmin in the range of 400° C. to 600° C. The substrate starting temperatures Tsu may not or only for a short time fall below the minimal required temperature of parts due to the coating-substrate-system characteristics to be maintained.

In steels for example (e.g. secondary hardened steels, HSS) usually a minimum temperature of parts Tmin of 400° C. up to 500° C. is intended. For hard metals usually temperatures up to 700° C. are realized.

It is self-evident, that in practice also coating tasks are present, which have to be performed in a temperature range between NTB and HTB. This is e.g. the case in brazed parts. Since this temperature range between NTB and HTB is only to be understood as a special case of HTB, there is no need for discussing this intermediate range here.

The coating chambers known from the state of the art are either designed in such a way, that in practice they can be operated with satisfying coating results only in a predetermined temperature range, e.g. in the above defined NTB, HTB or, in between. Or a modification of the coating chamber is disproportionally complex and thus uneconomical in total. These known coating systems, limited to certain temperature ranges, are limited also to certain substrate materials or coating types, respectively, coating compositions or characteristics of the realizable coating according to the explanations given above, leading to the fact, that several different coating chambers in one and the same production facility must be provided for the different substrate and coating types or at least a complex modification of the coating chambers must be accepted, if it is necessary to switch from one substrate type or from one coating type to another, respectively.

### SUMMARY OF THE EMBODIMENTS

Therefore, embodiments of the invention to provide an improved coating chamber for making different substrates and coatings or coating systems, respectively, in one and the same coating chamber under different temperature conditions, wherein a greatest possible flexibility of the coating systems is to be realized regarding the temperature of parts with the least possible process times. In particular, it should be possible to flexibly adapt the coating chamber to a required temperature range using not only very simple measures. In addition, special embodiments of coating chambers should be provided which have a significantly greater usable temperature range compared to the state of the art so that a great many of different substrates can be processed in one and the same coating chamber or a great many of different coating types, respectively, can be made without performing complex modifications when changing to another coating object. Further embodiments of the invention is to provide technical installations for a coating chamber for realizing the required characteristics to the coating chamber, wherein the technical installations particularly can be designed in such a way, that existing systems can be retrofitted. Furthermore, embodiments of the invention provide a novel coating process for realizing in a coating chamber according to the invention.

It is also an object of the invention to provide a solution, which allows to control the heat dissipation in a coating chamber in such a way, that the coating temperature does not rise uncontrollably due to an increase of the heat supply, but can be kept at the intended operating point.

The respective dependent claims relate to particularly advantageous embodiments of the invention.

Thus the invention relates to a coating chamber for performing a vacuum-assisted coating process, in particular PVD or CVD or arc discharge coating chamber or hybrid coating chamber. The coating chamber comprises a heat shield, which is arranged on a temperature-controllable chamber wall of the coating chamber and is intended for adjusting an exchange of a predeterminable amount of thermal radiation between the heat shield and the temperature-controllable chamber wall. According to the invention the heat shield comprises at least one exchangeable radiating shield, which is directly adjacent to an inner side of the chamber wall, wherein a first radiation surface of the radiating shield, that is directed to the chamber wall, has a first predeterminable heat exchange coefficient and a second radiation surface of the radiating shield, that is directed away from the chamber wall has a second predeterminable heat exchange coefficient, wherein the first heat exchange coefficient is greater than the second heat exchange coefficient.

It should be pointed out here, that the physical quantity which is referred to as “heat exchange coefficient” within this application is familiar to the person skilled in the art e.g. by the terms “emission degree” or “emission ratio” and can be measured according to methods known to the person skilled in the art.

The heat shield can further comprise a protection shield with a first protection surface, that is directed towards the chamber wall and a second protection surface, that is directed away from the chamber wall, wherein the first protection surface and/or the second protection surface each having a shiny reflecting surface with a processing status according to DIN EN10088 of at least 2D, preferred a processing status according to DIN EN10088 of at least 2R.

Before discussing below specific embodiments of the invention in detail, the essential basic features of the invention should be discussed in the following.

In practice a coating chamber according to the invention is preferably a double-walled chamber, which can be operated alternatively with cold or warm water for heat removal, under certain circumstances also with an oil or another thermostating fluid. Wherein, in special exceptional cases, a coating chamber according to the invention can also do without thermostating with a thermostating fluid like water or oil, e.g. when so little heat must be removed outward due to the process, that the heat output over the outer surfaces of the coating chamber or additional heat dissipating elements is sufficient.

Shield holders are provided inside the chamber at the chamber walls, which can receive shield components in the form of individual metal sheets as a single layer or as sheet bundles, which are preferred essentially geometrically identical but thermally different and thus generating the heat shield.

At least one radiating shield is particularly preferably installed as a heat shield on the inner chamber wall for low temperature coating (NTB) or in case of a high temperature coating (HTB) a modular stack of sheets, additionally comprising at least one protection shield. The essential operating principles of the radiating shield and the protection shield can be summarized as follows:

The radiating shield is preferred provided at the inner chamber wall in the form of a metal sheet and is, in particular, easy to remove or to replace for cleaning purposes. Thus the radiating shield fulfills a dual function and on the one hand it serves as a protection of the chamber wall against parasitic coatings and on the other hand it allows a sufficiently intense heat output by radiation to the chamber wall by heat radiation.

In particular the chamber wall may be also conditioned such, that a sufficient heat exchange is allowed by heat radiation between the radiating shield and the chamber wall. The radiation characteristics are particularly preferred tuned, in particular the heat exchange coefficients of chamber wall and radiating shield for optimal heat exchange.

But also the protection shield has a dual function. In practice, also the protection shield is often made as a metal sheet, provided at or in front of the chamber wall, respectively, which is also easy to remove for cleaning purposes. Thus, on the one hand the protection shield also protects the chamber wall against parasitic coatings and on the other hand it allows in contrast to the radiating shield a lowest possible heat dissipation caused by heat radiation in direction to the chamber wall or to a further metal sheet of the sheet bundles, which is arranged in direction to or in front of the chamber wall by heat radiation.

The chamber wall could be conditioned in such a way, that a lowest possible heat exchange occurs caused by heat radiation between the first metal sheet of the sheet bundles of the heat shield, located in direction of the chamber, and the chamber wall. However this is more or less incompatible with the requirements of low temperature coating NTB, in which a radiating shield is to be used. Thus the chamber wall is preferably conditioned in such cases, so that a maximum heat dissipation occurs caused by heat radiation to the chamber wall.

In the following, some calculation examples are listed to demonstrate the dominant importance of the coating of the radiating shield. As known in the art the maximum possible radiation exchange is given by the black-body radiator, having a heat exchange coefficient of ε_{Sch}=1. This means, if both the chamber wall and the radiating shield have a heat exchange coefficient of 1, the maximum possible radiation exchange is given between radiating shield and chamber wall. The values given below are the fractions obtained in measurements compared to the state of the ideal black-body radiator. The calculation examples clearly show the need of high values for the heat exchange coefficient of the radiation surfaces surfaces involved in case of the low temperature coating NTB.

The following assumptions are based on:
A) Best vacuum technical state of the surfaces for low desorption rates. The chamber wall (heat exchange coefficient=εₖ) and the directly adjacent radiation metal sheet (heat exchange coefficient=ε_{Blech}), are made of stainless steel and essentially mirror gloss polished. Then you get for the heat exchange coefficient:
εₖ=ε_{Blech}: 0.1+/−0.05 and thus for the effective total exchange coefficient ε_{ges}=0.053.
B) Frequently used in industrial manufacturing. Matt, scratched surfaces of the chamber wall and directly adjacent radiation metal sheet made of stainless steel, largely smooth:
εₖ=ε_{Blech}: 0.2+/−0.1 and thus the effective total exchange coefficient is ε_{ges}=0.111.
C) Blasting treatment for providing rough surfaces Chamber wall and directly adjacent radiation metal sheet, made of stainless steel, and rough blasted:
εₖ=ε_{Blech}: 0.4+/−0.1 and thus the effective total exchange coefficient is ε_{ges}0.25.
D) Chamber wall made of stainless steel, rough blasted, directly adjacent radiation metal sheet made of stainless steel, rough blasted, and coating having a great high exchange coefficient=ε_{Blech}:εₖ=0.4+/−0.1
ε_{Blech}=0.85+/−0.15 and thus the effective total exchange coefficient is ε_{ges}=0.374.
E) Chamber wall made of stainless steel, rough blasted, and coating having a high heat exchange coefficient=εₖ, directly adjacent radiation metal sheet made of stainless steel, rough blasted, and coating having
a hight heat exchange coefficient=ε_{Blech}:
εₖ=0.85+/−0.1
ε_{Blech}=0.85+/−0.15 and thus the effective total exchange coefficient is
ε_{ges}=0.74.
F) Ideal black-body radiator
εₖ=ε_{Blech}: 1 and thus the effective total exchange coefficient is ε_{ges}=1.

Of course, also the chamber temperature or also the temperature of the chamber wall have, respectively, an influence on the heat output of the radiating shield, because the heat exchange follows the fourth power of the temperature, well known. That is why a wall temperature should be set as low as possible for low temperature coating NTB, for example a cooling water temperature of a double-walled coating chamber of e.g. 20° C. or lower. To demonstrate this influence, a temperature of a radiating shield of 150° C. is chosen, for example, measured experimentally for NTB. If the chamber walls are not cooled with cold water, a temperature of 50° C. or even more often occurs during operation. The heat flow to the chamber wall is for a temperature of 20° C. by a factor of 1.16 higher than that to the chamber wall with 50° C.

While doing so, additionally a further effect for lowering the temperature of parts is realizable by the chamber cooling. Electrons often flow to the grounded chamber wall, thus increasing the temperature thereof inside the chamber with insufficient cooling, because the chamber lining is not lined electrically dense with radiating shields between the plasma and the plasma sources. Another amount of the electrons can directly contribute to the heating of the radiating shields, even if these are at chamber potential.

Thus both the chamber walls and the radiating shields can be heated by two different parts of a total heat input, whereby one part is given by the heat radiation through the thermostated parts to be coated, and the other part is determined by an electron flow, coming from the plasma or the plasma sources. This is particularly pronounced in the process of cathodic vacuum arc evaporation, often operating with the application of various evaporators with flows of a few 100 A to a few 1000 A, in total. Even using optimized magnetic fields for guiding the arc and anode arrangements around the evaporators, electrons flow to the grounded radiating shields. This electron effect is particularly pronounced, if no anode arrangements are constructively provided around the evaporator, but the chamber wall is the only anode. To prevent heating, it is a good solution to separate the radiating shields electrically from the chamber wall by an insulation element, so that the electrons flow to the cooled chamber wall and not to the radiating shield.

As discussed already, it is a crucial finding of the present invention, that the surface characteristics of the radiating shield, of the protection shield and of the chamber wall are of crucial importance. According to the invention, this results in a suitable conditioning or coating, respectively, of one or more components mentioned above.

Due to construction, the radiating shield according to the invention is a radiating dual function metal sheet with two differently designed sides as to radiation technique; the side facing the chamber wall and the side facing the parts to be coated.

In a special embodiment of the invention the side facing the chamber wall is treated by a blasting treatment with suitable, which is well known to the person skilled in the art, blasting device (corundum, SiC and others), adequate blasting pressures, adequate blasting angles and time, to realize a rough as possible (gray) working surface condition. The arithmetic middle roughness values (middle roughness), briefly Rₐ-values should have values about 1 μm±0.2 μm or greater up to 10 μm±0.2 μm. And have values for the middle roughness, briefly R_{z}-values about 10 μm±0.2 μm or greater up to 200 μm±20 μm. The side facing the chamber is then coated with a suitable black as possible coating, so that adherent black scratch-resistant as possible is applied. The coatings can be PVD-coatings, e.g. AlₓTi_{y}N, preferably Al₆₆Ti₃₃N but also AlCrN, preferably with the same composition but also other PVD-coatings. The coatings are deposited optically dense. As a rule a coating thickness of 500 nm is sufficient. However the coating thicknesses can be thicker, e.g. in the range up to a few um. Another possibility is the coating with suitable DLC-coatings, e.g. a-C, a-C:H, a-C.H:X, a-C:H:Me.

The side facing the parts to be coated as well as the side facing the chamber wall is roughened by a blasting treatment. But the epsilon value of the heat exchange coefficient over the process time is usually changed, because depending on the coating process and the coatings to be applied to the parts, unavoidable different deposits with parasitic coatings occur. Ideally for the heat output to the chamber wall, black coatings are formed as in DLC-coating processes, but in other cases also metallic gray coatings as present regarding CrN-coating or gold-colored coatings as present in TiN-coatings by cathodic vacuum arc coating. However, an essential finding of the invention is, that the rough surface ensures the best possible heat exchange among parts to be coated of the cold chamber wall, independent of the parasitic deposits. The radiating shield is treated by another blasting treatment after each cycle or when the parasitic coating are applied to thick. That is why the coated side facing the chamber wall needs a coating, abrasion-resistant as possible, so as not to be damaged during this reconditioning process. In particular AlTiN-coatings, deposited by the cathodic vacuum arc evaporation fulfill this function in an excellent way.

A suitable conditioning or coating of the chamber wall, respectively, can for example be performed as follows. The chamber wall is treated by a blasting treatment with suitable, well known to the person skilled in the art, blasting device (corundum, SiC and others) and adequate blasting pressures, to realize an acting surface condition as rough as possible (gray). Rₐ-values should be values about 1 μm±0.2 μm or greater up to 10 μm±0.2 μm, R₂-values about 10 μm±0.2 μm or greater up to 100 μm±20 μm.

Additionally, a coating of the chamber wall can alternatively be performed with black coatings. These should be electrically conductive. Black PVD-coatings and conductive DLC-coatings are possible here, as already described for the radiating shield configured in the form of a radiating dual function metal sheet.

In the following, some important comments to the characteristics of the protection shield are provided. In practice, this type of shields virtually is always a smooth as possible metal sheet, ideally with mirror gloss, in order to ensure the lowest possible heat flow. The side facing the chamber has a shiny reflecting surface with a processing status according to DIN EN10088 of at least 2D, preferred a processing status according to DIN EN10088 of at least 2R, whereby measurements of roughness exclude unavoidable scratches, caused in handling the metal sheets or areas where assembly elements are, respectively. The side facing the parts to be coated is namely also smooth in a new condition, but depending on the coating process and the coatings to be applied to the parts, the surface is differently changed concerning roughness and heat exchange coefficient Epsilon during the coating process. Though the set roughness is such, that the heat transfer to the chamber wall is minimized.

In the following, a preferred embodiment of a coating chamber according to the invention for performing a high temperature coating process HTB according to the invention is briefly sketched. In order to reduce the heat transfer to the chamber wall, which should be as high as possible for the NTB, and to modify for the HTB by using the radiating shield, which is coated in direction to the chamber wall and cooperates with the rough chamber wall as described, at least one protection shield, which is geometrically identical or very similar is additionally installed. Then the radiating shield operates like a radiation protective shield. Further protection metal sheets are preferably provided between the radiating shield and the protection shield. If the chamber wall is made double-walled, it can be preferably cooled with warm water of about 50° C. instead of cold water for minimizing the heat radiation to the chamber.

Regarding a particular preferred embodiment, three drawn metal sheets made of stainless steel (DIN 1.4301) with a thickness of 1 mm are used for the heat shield in form of a metal sheet system. The roughness in areas without unavoidable scratches was in the range of Rₐ=0.8 μm±0.16 μm and R_{z}=6 μm±1.2 μm. The heat exchange coefficient of this surfaces was determined to be 0.15+/−0.5. The blasting treatment of a metal sheet, which was used for the radiating shield, was made by a dry blasting process with corundum. Thus the roughness set was Rₐ=7 μm±1.4 μm R_{z}=60 μm±12 μm. Then this radiating shield was coated by a PVD-process, the cathodic vacuum arc evaporation, with a black AlTiN by using cathodes of the composition Al66Ti34 with a coating thickness of 1 μm. The heat exchange coefficient of this surface was measured to be 0.83+/−0.5. The double-walled coating chamber used was blasted for the PVD-process based on the cathodic vacuum arc evaporation inside the chamber. The middle roughness was Rₐ=5 μm±1 μm and R_{z}=48 μm±9.6 μm. A heat shield was installed for the HTB in form of a metal sheet system with a radiating shield, a protection metal sheet located thereon and a protection shield located thereon again. The temperatures required for the HTB of 500° C. were reached also when using a cooling water temperature of 20° C.

Both the protection shield and the protection metal sheet were removed for the NTB at ca-200° C. Only the one-sided coated radiating shield was at the chamber wall. The cooling water temperature was maintained at 20° C. That's why a continuous coating process could be made with the required temperatures without interrupting the process.

Regarding a particular preferred embodiment in practice, the first radiation surface or the second radiation surface is made rough for setting the first predeterminable heat exchange coefficient or the second predeterminable heat exchange coefficient of the radiating shield, in particular a roughness of Rₐ=1 μm±0.2 μm to 10 μm±2 μm or a roughness of R_{z}=10 μm±2 μm to 100 μm±20 μm is provided, which has proved to be the optimum parameter of the roughness for the intended heat exchange rates, as discussed above.

Compared to the black heat exchange coefficient of the black body radiator with ε_{Sch}=1.0, the first radiation surface is particularly advantageous a black surface or alternatively or simultaneously a surface coating with a high first heat exchange coefficient in the range of 0.1 to 1.0, in particular between 0.5 and 0.95, particularly preferred between 0.7 and 0.9, wherein the first heat exchange coefficient is particularly preferred in the range of about 0.85.

As discussed above, the first radiation surface and/or the second radiation surface comprises the mentioned surface coating, in particular comprising a coating, deposited by PVD, in particular an AlₓTi_{y}N, preferred an Al₆₆Ti₃₃N and/or an AlCrN, in particular an Al₆₆Cr₃₃N coating, and/or comprising a suitable DLC-coating, in particular an a-C, a-C:H, a-C.H:X, a-C:H:Me coating, wherein the coating is preferred an optically dense deposited coating and/or has a coating thickness of 100 nm up to several 1000 nm, in particular between 300 nm to 800 nm and particularly preferred at least 500 nm.

Though the heat shield can also comprise even only one radiating shield only coated on the first radiation surface, in particular for using in low temperature coating processes in the range of up to a maximum temperature of parts of about 250° C., so that a sufficient great heat transfer is ensured to the chamber wall from the parts to be coated inside the coating chamber.

In contrast, also one or a plurality of further radiation shields can be provided between the radiating shield, which is directly adjacent to the chamber wall and the protection shield, in particular up to three additional radiation shields between the radiating shield and the protection shield, in particular when the parts should be coated at higher temperatures, e.g. in the HTB range or at temperatures between the NTB range or the HTB range.

For a safe mounting on a shield holder, the radiating shield and/or the protection shield and/or the radiation shield each comprise an assembly area, which is arranged in such a way, that the corresponding radiation metal sheet with the assembly area can be fixed to a holding device of a shield holder at the chamber wall, preferred all radiation metal sheets simultaneously by one and the same shield holder. The radiation metal sheets can be screwed to the shield holder for example, clamped in a groove of the shield holder or connected in another manner to the shield holder, preferably detachable.

Thereby the radiating shield and/or the protection shield and/or the radiation shield is arranged in particular advantageously identically geometrical such, at least in the assembly area, such that they can be used interchangeably in in each holding device of the shield holder, so that different characteristics of the heat exchange can be flexibly set between the chamber wall and the heat shield. Simply by e.g. changing the arrangement of the radiation metal sheets as required.

Thereby, as discussed above, the radiating shield and/or the protection shield and/or the radiation shield can be electrically insulated connected with the chamber wall, so that an additional heating by free charge carriers in the coating chamber, e.g. by electrons or ions, is at least significantly reduced, respectively substantially avoided.

In practice, the coating chamber itself usually has a double-walled chamber wall, so that a thermostating fluid is circulable inside the double-walled chamber wall in order to thermostate it, usually with simply pre-thermostated water or non-thermostated water, an oil, or another suitable thermostating fluid.

Thereby also the inner side of the chamber wall can be roughened and has, for example, a roughness in the range of Rₐ=1 μm±0.2 μm to 10 μm ±2 μm and/or of R₂=10 μm±2 μm to 100 μm±20 μm. Thereby, compared to the black heat exchange coefficient of the black body radiator with ε_{Sch}=1.0, the inner side can have a black coating with a great chamber exchange coefficient in the range of 0.1 to 1.0, in particular between 0.2 and 0.8, particularly preferred between 0.3 and 0.6, in particular a chamber exchange coefficient in the range of about 0.4.

Also the inner side of the chamber wall can have a chamber coating analogous to the radiation metal sheets, in particular comprising a coating, deposited by PVD, in particular an AlₓTi_{y}N, preferred an Al₆₆Ti₃₃N and/or an AlCrN, in particular an Al₆₆Cr₃₃N coating, and/or comprising a suitable DLC-coating, in particular an a-C, a-C:H, a-C.H:X, a-C:H:Me coating, wherein the coating is preferred an optically dense deposited coating and/or has a coating thickness of 100 nm up to several 1000 nm, in particular between 300 nm to 800 nm and particularly preferred at least 500 nm.

Further embodiments of the invention are directed to a heat shield for a coating chamber according to the present invention, the heat shield being particularly a retrofit component, so that also existing coating chambers may be retrofitted with a heat shield according to the invention, as described above.

Furthermore the invention also relates to a coating process by using a heat shield and a coating chamber according to the described invention, the coating process being a PVD-process, in particular a PVD-process comprising magnetron sputtering and/or HIPIMS, or a plasma-assisted CVD process or a cathodic or an anodic vacuum arc evaporation process or a combination method made of these processes or another vacuum-assisted coating process, whereby depending on the coating process used or the coating to be applied, an optimally configured heat shield is selected and used for setting optimal coating temperatures.

In particular the coating process can be a low temperature coating process and the coating chamber is thermostated by a thermostating fluid, in particular water or oil with a temperature in the range of 10° C. to 30° C. Or the coating process according to the invention can also be a high temperature coating process, or a coating process, which is performed in a temperature range between a NTB and a HTB process, whereby the coating chamber is thermostated with the thermostating fluid, in particular water or oil with a temperature in the range of 30° C. to 80° C., preferred in a temperature range of 40° C. to 60° C.

### BRIEF DESCRIPTION OF THE DRAWINGS

The invention will be explained in more detail with reference to the schematic drawings. It is shown:

FIG. 1 schematically, a coating chamber according to the invention;

FIG. 2 a coating chamber with only one radiating shield;

FIG. 3 a coating chamber with radiating shield, protection shield, and radiation shield for HTB operation

FIG. 4 a schematic presentation of the arrangement of basic elements of a vacuum chamber according to the present invention.

FIG. 5 the course of the temperature of substrates to be treated, each were treated in a vacuum chamber to the state of the art (broken line) and in a vacuum chamber according to the invention (solid line).

### DETAILED DESCRIPTION OF THE EMBODIMENTS

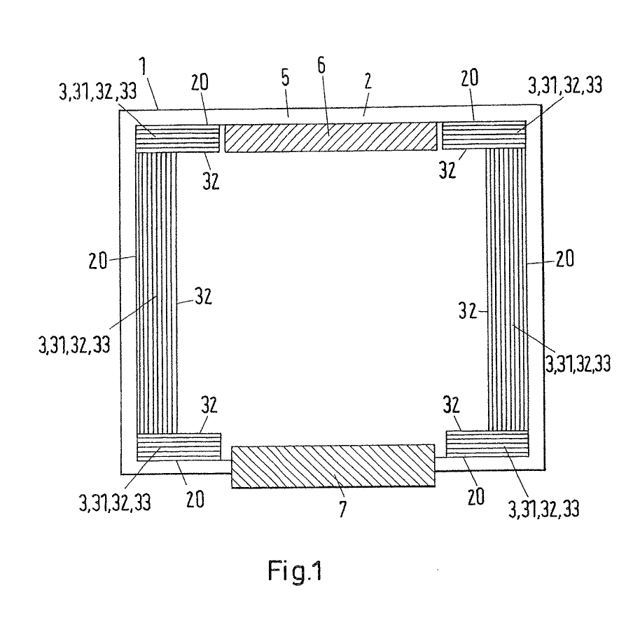

FIG. 1 schematically shows a first simple embodiment of a coating chamber according to the invention, which e.g. can be used particularly advantageously for performing a high temperature coating process.

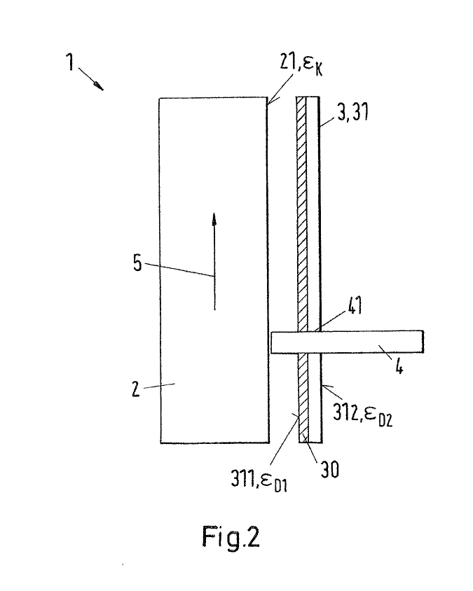

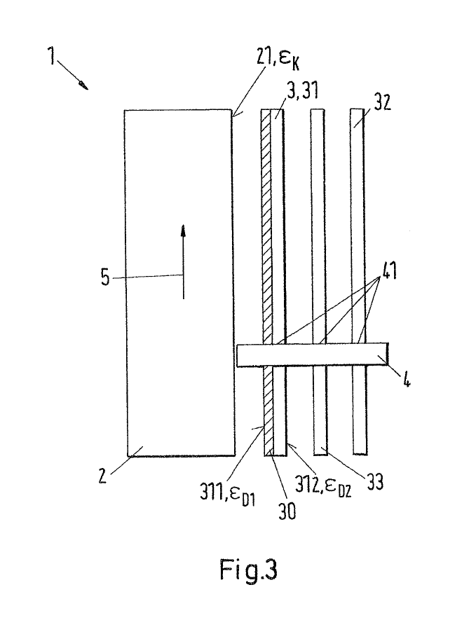

The coating chamber 1 according to the invention for performing a vacuum-assisted coating process according to FIG. 1 comprises a heat shield 3, 31, 32, 33, which is arranged on a temperature controllable chamber wall 2 of the coating chamber and is intended for adjusting an exchange of a predeterminable amount of thermal radiation between the heat shield 3, 31, 32, 33 and the temperature-controllable chamber wall 2. According to the present invention the heat shield 3, 31, 32, 33 comprises an exchangeable radiating shield 31, which is directly adjacent to an inner side 21 of the chamber wall 2, having a first radiation surface 311 of the radiating shield 31, that is directed towards the chamber wall 2, with a first predeterminable heat exchange coefficient ε_{D1}, whereby a second radiation surface 312 of the radiating shield 31, that is directed away from the chamber wall 2 has a second predeterminable heat exchange coefficient ε_{D2}, and the first heat exchange coefficient ε_{D1} is higher than the second heat exchange coefficient ε_{D2}. For reasons of clarity, the radiating shield 32 in FIG. 1 is not shown in detail. The specific structure of the radiating shield 31 is essentially identical to that of FIG. 2 or FIG. 3, respectively, so that for details of the structure of the radiating shield 32 it can be referred to FIG. 2 or FIG. 3, respectively.

The coating chamber 1 comprises in a manner known per se in the art, a heater for pre-heating the parts to be coated, which are during operation e.g. on a rotating part holder inside the coating chamber 1 and are not shown here, as well as plasma sources 7 for coating, which are also known in many variations from the state of the art. Details as e.g. the heater, the plasma sources, the part holder for the parts to be coated etc. are of little importance for the understanding of the invention.

A plurality of further radiation shields 33 is provided between the radiating shield 31, which is directly adjacent to the chamber wall and the protection shield 32 between the radiating shield and the protection shield 32.

The coating chamber 1 itself has a double-walled chamber wall 2, so that a thermostating fluid 5, here water, is circulable inside the double-walled chamber wall 2 for thermostating.

The inner side 21 of the chamber wall 2 is either only rough blasted and/or provided with a chamber coating 20, comprising a coating, deposited by PVD, e.g. an AlₓTi_{y}N, an AlCrN coating or a suitable DLC-coating comprises, wherein the coating is an optically dense deposited coating has a coating thickness of 100 nm up to several 1000 nm.

FIG. 2 shows a special coating chamber having only one radiating shield 31 for NTB operation. Thus the heat shield 3 consists of even only one radiating shield 31 only coated on the first radiation surface 311 for using use in low temperature coating processes in the range of up to a maximum temperature of parts of about 250° C.

For adjusting the first predeterminable heat exchange coefficient ε_{D1} and the second predeterminable heat exchange coefficient ε_{D2} of the radiating shield 31, the first radiation surface 311 and the second radiation surface 312 are rough and have a roughness of Rₐ=1 μm±0.2 μm to 10 μm±2 μm respectively a roughness of R_{z}=10 μm±2 μm to 100 μm±20 μm.

Additionally the first radiation surface 311 is provided with a surface coating 30, which has a high first heat exchange coefficient ε_{D1} in the range of 0.7 to 0.9, compared to the black heat exchange coefficient ε_{Sch} of the black body radiator with ε_{Sch}=1.0.

The surface coating 30 is a coating, deposited by PVD, especially an AlₓTi_{y}N, an AlCrN, or a suitable DLC-coating, especially an a-C, a-C:H, a-C.H:X, a-C:H:Me coating, whereby the coating is an optically dense deposited coating and has a coating thickness of 100 nm up to several 1000 nm. e.g. 500 nm.

The radiating shield 31 is fixed to a holding device 41 of a shield holder 4 by a shield holder 4 at the chamber wall 2 in an assembly area, whereby the radiating shield 41 is a radiating metal sheet, which is simply clamped in a holding device 41 of the shield holder configured as a groove so that it can be replaced easily and quickly.

Finally, in FIG. 3 a special embodiment of a coating chamber 1 is shown with radiating shield 31, protection shield 32 and radiation shield 33, arranged in between. This arrangement is particularly suitable for high temperature operation.

In a further embodiment, the present invention relates to a vacuum chamber and a coating system with a special arrangement to increase heat dissipation.

Conventional coating systems are usually designed in such a way, that a predeterminable coating temperature inside the coating chamber or of the recipient, respectively can be realized and maintained. The surfaces inside the coating chamber are often made of shiny or blasted stainless steel or aluminum. Since the inner walls of the coating chamber can be undesirably coated during performing coating processes, a shielding is usually used, in order to avoid the build-up of thicker coatings on the inner walls. Above all, the use of such a shielding is very helpful, when several coating processes should be performed one after the other without service and, as a result, several coatings accumulate on one another and flaking occurs during coating and after coating. Such a shielding is often also made of shiny or blasted stainless steel or aluminum. This design is normally applied uniformly throughout the recipient respectively along the outer surface, the top surface and the bottom surface.

Coating sources, heating and cooling elements are usually distributed inside the coating chamber as individual components in such a way, that some inner surfaces or inner chamber wall surfaces, respectively, will remain free of sources and/or elements. As a result these “free” surfaces act as heat removing elements or in a manner similar to cooling elements, respectively.

Usually the relation between heat supply by heating and coating sources for example, and heat removal through the outer surface of the coating chamber plays an important role when adjusting the operating point of the system regarding coating temperature, in particular when both the top surface and the bottom surface are thermally insulated. Thermally insulation of top surfaces and bottom surfaces results in a homogeneous distribution of temperature over the coating height, even if, for example, operating heaters without temperature control.

Already when starting a coating process a determined temperature, i.e. a determined temperature of the substrate surface to be coated should be realized. Heating elements are often arranged on a chamber wall surface for heat supply, at least until starting the coating process, so that these warm surfaces emit heat to the substrate.

After starting and during operating the coating process, an additional heat supply is produced by operating the coating sources, which can be particularly high when operating a great number of arc evaporation sources with high arc currents.

If substrates in a coating system were coated with a certain coating, but it was intended to establish an increased coating rate, this could be realized by using, for example, an increased number of coating sources. But in this case a corresponding increase in heat supply into the coating chamber must be expected, resulting directly in an increase of the coating temperature, if the heat removal is not accordingly adjusted or increased. This problem is particularly severe, when using arc evaporation sources.

Further embodiments of the invention is to provide a solution, which makes it possible to control the heat removal in a coating chamber in such a way, that the coating temperature does not rise uncontrolled due to an increase in the heat supply but can be held at the desired operating point.

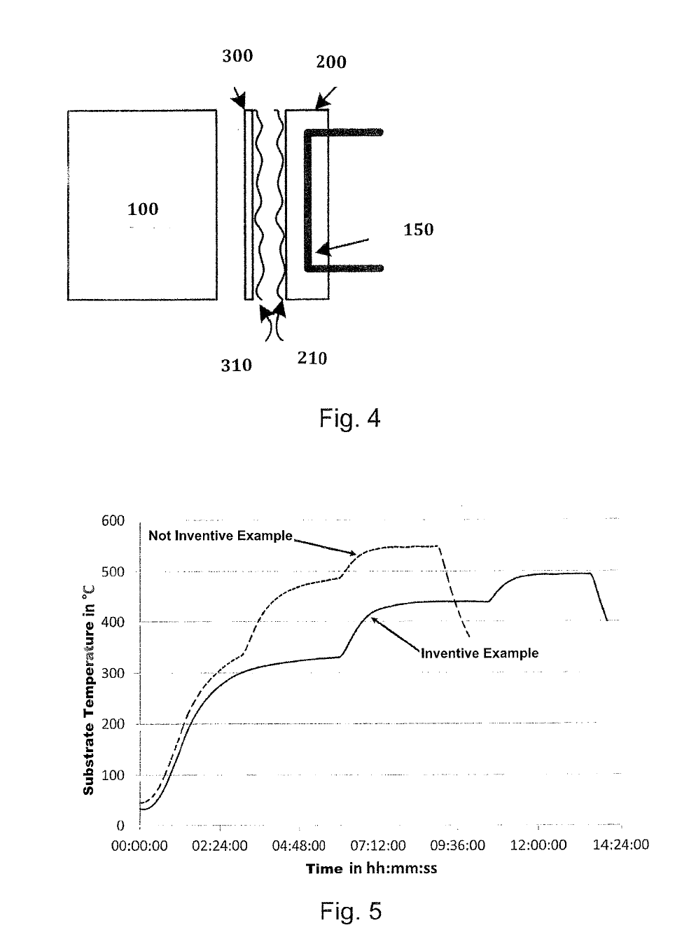

For a better understanding of the above mentioned facts of the present invention, it is referred to FIGS. 4 and 5:
FIG. 4 shows a schematic representation of the arrangement of basic elements of a vacuum chamber according to the present invention.
FIG. 5 shows the course of the temperature of substrates to be treated, each were treated in a vacuum chamber from the state of the art (broken line) and in a vacuum chamber according to the invention (solid line).

The present invention basically discloses a vacuum chamber for treating substrates, comprising at least the following elements:
heat supply elements for the heat supply into a treatment area of the vacuum chamber, in which at least one substrate 100 can be treated,
a chamber wall 200, through which heat can be removed from the treatment area, comprising an inner and an outer chamber wall side, and:
a shielding wall 300, which is arranged between the chamber wall 200 and the treatment area, such that an averted shielding wall side with respect to the treatment area is placed opposite the inner chamber wall side,
   and characterized in, that
the shielding wall side placed opposite the inner chamber wall side is at least partially, preferred largely applied with a first coating 310 which has an emission coefficient ε≥0.65.

According to a preferred embodiment of the present invention, the inner chamber wall side is also at least partially, preferably at least largely applied with a second coating 210, which has an emission coefficient ε≥0.65.

According to a further preferred embodiment of the present invention the chamber wall 200 comprises an integrated cooling system 150.

The emission coefficient of the first coating 310 is preferably greater than or equal to 0.80, more preferably greater than or equal to 0.90.

The emission coefficient of the second coating 210 is also preferably higher than or equal to 0.80, more preferably higher than or equal to 0.90.

Generally, the inventors have observed a particularly significant increase in heat removal from ε≥0.8, in particular from ε≥0.9. Even more preferably ε is close to 1.

According to another preferred embodiment of the present invention the first coating 310 and/or the second coating 210 are deposited at least partially by a PVD-process and/or a PACVD-process (PVD: Physical Vapor Deposition; PACVD: Plasma assisted chemical vapor deposition).

According to another preferred embodiment of the present invention the first coating 310 and/or the second coating 210 comprises aluminum and/or titanium.

Also preferred the first coating 310 and/or the second coating 210 comprises nitrogen and/or oxygen.

The inventors have also found, that coatings comprising titanium aluminum nitride or aluminum titanium nitride or are of titanium aluminum nitride or aluminum titanium nitride, are very suitable as first coating 310 and/or second coating 210 in the context of the present invention.

Also coatings comprising aluminum oxide or consisting of aluminum oxide are well suited as first coating 310 and/or second coating 210 in the context of the present invention.

The present invention also discloses a coating system with a vacuum chamber according to the invention as coating chamber as described above.

According to a preferred embodiment of a coating system according to the invention, the coating chamber is established as a PVD-coating chamber.

A shielding wall 300 is preferably provided for reducing or avoiding coating of the inner chamber wall side during performing a PVD-process inside the PVD-coating chamber.

Both top surfaces and bottom surfaces of the PVD-coating chamber are preferably thermally insulated, to realize a more homogeneous distribution of temperature over the coating height (respectively over the entire height of the treatment area).

The chamber wall 200 or the chamber walls 200, respectively, are preferably not provided with functional elements such as coating elements, plasma treating elements or heating elements.

As required, all chamber walls 200, at which preferably no such functional elements are arranged, can be provided with a second coating 210 in the inner chamber wall side and provided with a shielding wall 300 with a first coating 310 according to the present invention.

It can also be advantageous, that all these chamber walls 200 are provided with integrated cooling systems 150 for realizing an even higher heat removal.

As already mentioned above, FIG. 5 shows the comparison of the course of the substrate temperature in the same vacuum chamber, whereby once for the embodiment according to the invention, shielding walls 300 and chamber walls 200, as described above, are provided with corresponding first coatings 310 and second coatings 210 according to the invention (solid line), and another time for the example to the state of the art the same vacuum chamber arrangement was used, but without coatings 310 and 210 (broken line). Both examples were performed with equal heat supply into the coating chamber.

For the above mentioned embodiment according to the invention, a PVD deposited titanium aluminum nitride coating with an emission coefficient ε from about 0.9 was used as first coating 310 as well as second coating 210.

According to a preferred embodiment of the present invention the inner side of all shielded chamber walls can be coated at least largely with a corresponding second coating 210 and the side of all shielding walls opposite to the chamber walls at least largely with a corresponding first coating 310.

According to the present invention both the coating 210 and the coating 310 should be made of materials, which are vacuum suitable. It is also important, that these materials are not magnetic, to avoid malfunctions during coating.

The coatings 210 and/or 310 preferably have at least one of the following characteristics:
a coating thickness not larger than 50 μm,
a dense coating structure, so that there is possibly no outgassing by the coating,
a good adhesion to the carrier material for ensuring a good heat transfer,
a high temperature stability, which allows performing coating processes at increased temperatures, preferred up to at least 600° C.,
good abrasion resistance, so that these coatings are not rapidly worn off in a “harsh production environment”.

The coatings 210 and/or 310 are preferably deposited by PVD techniques, so that they can be applied, for example, on the corresponding chamber wall sides and shielding walls sides in the same coating chamber. In this case, for example, the inner chamber walls can first be coated with the coating 210 without shielding walls in a coating process. Afterwards, however, the shielding walls can be placed in the opposite direction in the coating chamber, so that the desired shielding wall side, which will be later opposite the inner chamber wall side, can be coated with the coating 310. A single application of the coatings 210 and 310 is sufficient, in order to operate the coating system several times with a coating chamber provided according to the invention.

For performing a PVD coating process for coating substrates in a coating chamber according to the invention, the shielding walls are arranged in the coating system such, that the inner chamber walls or the inner side of the chamber walls, respectively, are protected, in order to minimize or to avoid an undesired coating of these walls. In this way, basically only the shielding wall side without a coating 310 is also coated during the coating of substrates. Therefore both the applied coating 310 and the applied coating 210 remain intact after each coating process.

Needless to say, that the described embodiments are to be understood only as examples and that the extent of protection is not limited to the explicitly described embodiments. In particular each suitable combination of embodiments is also comprised by the invention.

1. A coating chamber for performing a vacuum-assisted coating process, comprising:
a temperature-controllable chamber wall;
a heat shield, which is arranged on the temperature-controllable chamber wall, for an exchange of a predeterminable amount of thermal radiation between the heat shield and the temperature-controllable chamber wall
wherein the heat shield comprises at least one exchangeable radiating shield, which is directly adjacent to an inner side of the chamber wall, having a first radiation surface directed towards the chamber wall with a first predeterminable heat exchange coefficient (ε_{D1}) and a second radiation surface directed away from the chamber wall with a second predeterminable heat exchange coefficient (ε_{D2}), and
wherein the first heat exchange coefficient (ε_{D1}) is greater than the second heat exchange coefficient (ε_{D2}).

2. The coating chamber according to claim 1, wherein the heat shield further comprises at least one protection shield having a first protection surface directed towards the chamber wall and a second protection surface directed away from the chamber wall,
wherein each of the first and second protection surfaces have a shiny reflecting surface with a processing status according to at least one of DIN EN10088 of at least 2D and DIN EN10088 of at least 2R.

3. The coating chamber according to claim 1, wherein at least one of the first radiation surface for adjusting the first predeterminable heat exchange coefficient (ε_{D1}) and the second radiation surface for adjusting the second predeterminable heat exchange coefficient (ε_{D2}) of the radiating shield is rough.

4. The coating chamber according to claim 1, wherein the first radiation surface has at least one of a black surface and a surface coating with a high first heat exchange coefficient (ε_{D1}) in the range of at least one of:
1 0.1 to 1.0,
between 0.5 and 0.95,
between 0.7 and 0.9,
approximately 0.85, compared to a black heat exchange coefficient (ε_{Sch}) of a black radiator with ε_{Sch}=1.0.

5. The coating chamber according to claim 2, wherein at least one of the first radiation surface and the second radiation surface comprises a surface coating wherein the surface coating at least one of:
is an optically dense deposited coating;
has a coating thickness of 100 nm to a few 1000 nm;
has a coating thickness between 300 nm to 800 nm, and
has a coating thickness of at least 500 nm.

6. The coating chamber according to claim 5, wherein, for applying low temperature coatings in a range of up to a maximum temperature of parts of 250° C., the heat shield comprises exactly only one radiating shield, which is coated only on the first radiation surface.

7. The coating chamber according to claim 2, further comprising one or more additional radiation shields arranged between the radiating shield and the protection shield.

8. The coating chamber according to claim 7, wherein at least one of the radiating shield, the protection shield and the radiation shield comprise an assembly area and is fixed to a holding device of a shield holder at the chamber wall in an assembly area.

9. The coating chamber according to claim 7, wherein the radiating shield, the protection shield and the radiation shield are geometrically designed at least in the assembly area in such an identically manner, that they can be applied interchangeably in each holding device, so that different characteristics of the heat exchange can be adjusted flexibly between the chamber wall and the heat shield and
wherein at least one of the radiating shield, the protection shield and the radiation shield is connected electrically insulated with the chamber wall.

10. The coating chamber according to claim 1, wherein the coating chamber comprising a double-walled designed chamber wall, so that a thermostating fluid, especially water or an oil, is circulable inside the double-walled chamber wall for thermostating.

11. The coating chamber according to claim 1, wherein at least one of:
the inner side of the chamber wall has a roughness in the range of at least one of: Ra=1 μm±0.2 μm to 10 μm±2 μm and Rz=10 μm±20 μm, and
the inner side has a coating with a high chamber exchange coefficient (ε_{K}) in the range of at least one of:
0.1 to 1.0,
between 0.2 and 0.8,
between 0.3 and 0.6, and
approximately 0.4, compared to a black heat exchange coefficient of a black radiator with ε_{Sch}=1.0.

12. The coating chamber according to claim 1, wherein the inner side of the chamber wall comprises a chamber coating, wherein the chamber coating at least one of:
is an optically dense deposited coating;
has a coating thickness of 100 nm to a few 1000 nm;
has a coating thickness between 300 nm to 800 nm, and
has a coating thickness of at least 500 nm.

13. A heat shield for a coating chamber according to claim 1, wherein the heat shield is a retrofit part.

14. A coating process using the coating chamber according to claim 1 and the heat shield is a retrofit part, the method comprising:
coating a substrate via at least one of:
a PVD process,
a PVD process comprising magnetron sputtering,
HIPIMS, or
a plasma-assisted CVD process,
a cathodic or an anodic vacuum arc vaporization process or
a combination process formed of these processes or another vacuum-assisted coating process.

15. Coating process according to claim 14, wherein at least one of:
the coating process is a low temperature coating and the coating chamber is thermostated by a thermostating fluid, especially water or oil, from a temperature in the range of 10° C. to 30° C., and
the coating process is a high temperature process and the coating chamber is thermostated with the fluid, in particular water or oil with a temperature in the range of 40° C. to 60° C.

16. The coating chamber according to claim 3, wherein the at least one of the first radiation surface and the second radiation surface has at least one of a roughness of Ra=1 μm ±0.2 μm to 10 μm±2 μm and/or a roughness of Rz=10 μm±2 μm to 100 μm±20 μm.

17. The coating chamber according to claim 5, wherein the surface coating comprises a coating that is at least one of deposited by PVD, a Al₆₆Cr₃₃N coating, and a suitable DLC-coating, and the coating has a coating thickness of 300 nm to 800 nm and in particular at least 500 nm.

18. The coating chamber according to claim 17, wherein the surface coating deposited by PVD comprises at least one of AlₓTi_{y}N, Al₆₆Ti₃₃N and an AlCrN and the DLC-coating comprises an a-C, a-C:H, a-C.H:X, a-C:H:Me coating.

19. The coating chamber according to claim 7, wherein the one or more additional radiation shields comprises up to three radiation shields arranged between the radiating shield and the protection shield.

20. The coating chamber according to claim 12, wherein the chamber coating comprises a coating that is at least one of deposited by PVD, a Al₆₆Cr₃₃N coating, and a suitable DLC-coating, and the coating has a coating thickness of 300 nm to 800 nm and in particular at least 500 nm.

21. The coating chamber according to claim 20, wherein the chamber coating deposited by PVD comprises at least one of AlₓTi_{y}N, Al₆₆Ti₃₃N and an AlCrN and the DLC-coating comprises an a-C, a-C:H, a-C.H:X, a-C:H:Me coating.
